(19) United States
(12) Patent Application Publication
(10) Pub. No.: US 2004/0180297 A1
(43) Pub. Date: Sep. 16, 2004

(54) Method for forming pattern in semiconductor device

(76) Inventors: Jooyoung Yoon, Seoul (KR); Sungoh Chun, Seoul (KR)

Correspondence Address: ST. ONGE STEWARD JOHNSTON & REENS, LLC, 986 BEDFORD STREET, STAMFORD, CT, 06905-5619, US

(21) Appl. No.: 10/798,998

(22) Filed: Mar. 12, 2004

(30) Foreign Application Priority Data
Mar. 12, 2003 (KR) 10-2003-0015557

(51) Int. Cl. G03F 7/26

(52) U.S. Cl. 430/316; 430/311; 430/313

(57) ABSTRACT

Disclosed is a method for forming a fine pattern of a semiconductor device in which the spacing between neighboring lines is reduced to be less than the resolution limit of a lithographic process. The method includes the steps of: (a) sequentially forming a base layer to be patterned, a lower photoresist layer, a blocking layer and an upper photoresist layer on a substrate; (b) forming the first photoresist pattern on the upper photoresist layer, and etching the blocking layer according to the first photoresist pattern; (c) forming the second photoresist pattern on the lower photoresist layer, which is opened by the spacing of the first photoresist pattern, wherein the spacing of the first photoresist pattern is greater than a line width of the second photoresist pattern; (d) etching the base layer using the second photoresist pattern as a mask; and (e) stripping the remaining photoresist layer.

This application relies for priority upon Korean Patent Application No. 2003-15557, filed on Mar. 12, 2003, the contents of which are herein incorporated by reference in their entirety.

### FIELD OF THE INVENTION

The present invention relates to a method for forming a pattern in a semiconductor device, and more particularly to a method for forming a fine pattern in which the spacing between neighboring lines is reduced to be less than the resolution limit of a lithographic process, thereby increasing the integration density of the semiconductor device.

### BACKGROUND OF THE INVENTION

With the development of manufacturing technologies of a semiconductor device such as a nonvolatile memory device, the pattern size of the semiconductor device decreases, and the integration density thereof increases. However, there is an unavoidable limitation in increasing the integration density due to the resolution limit of a lithographic process. Namely, it is impossible to reduce the spacing between neighboring pattern lines (for example, gate electrodes, active regions, metal layers) of the semiconductor device to be less than a predetermined size due to the resolution limit of a lithographic process.

SUMMARY OF THE INVENTION

Accordingly, an object of the present invention is to provide a method for forming a pattern of a semiconductor device, in which the spacing between neighboring lines is reduced to be less than the resolution limit of a lithographic process. Other object of the present invention is to provide a method for forming a pattern of a semiconductor device having an improved integration density.

In order to achieve these and other objects, the present invention provides a method for forming a pattern of a semiconductor device, which comprises the steps of: (a) sequentially forming a base layer to be patterned, a lower photoresist layer, a blocking layer and an upper photoresist layer on a substrate; (b) forming the first photoresist pattern on the upper photoresist layer, and etching the blocking layer, according to the first photoresist pattern; (c) forming the second photoresist pattern on the lower photoresist layer, which is opened by the spacing of the first photoresist pattern, wherein the spacing of the first photoresist pattern is greater than a line width of the second photoresist pattern; (d) etching the base layer using the second photoresist pattern as a mask; and (e) stripping the remaining photoresist layer.

### BRIEF DESCRIPTION OF DRAWINGS

The foregoing aspects and many of the attendant advantages of this invention will become more readily appreciated as the same becomes better understood by reference to the following detailed description, when taken in conjunction with the accompanying drawings, wherein;

FIGS. 1-3 are cross-sectional views for illustrating a process for forming a pattern of a semiconductor device using a conventional lithographic technology; and

FIGS. 4-9 are cross-sectional views for illustrating a process for forming a pattern of a semiconductor device according to an embodiment of the present invention.

### DETAILED DESCRIPTION OF THE INVENTION

It is to be understood and appreciated that the process steps and structures described below do not cover a complete process flow. The present invention can be practiced in conjunction with various integrated circuit fabrication techniques that are used in the art, and only so much of the commonly practiced process steps are included herein as are necessary to provide an understanding of the present invention. It should also be noted that the accompanying drawings are in greatly simplified form and they are not drawn to scale. Moreover, dimensions have been exaggerated for clear understanding of the present invention.

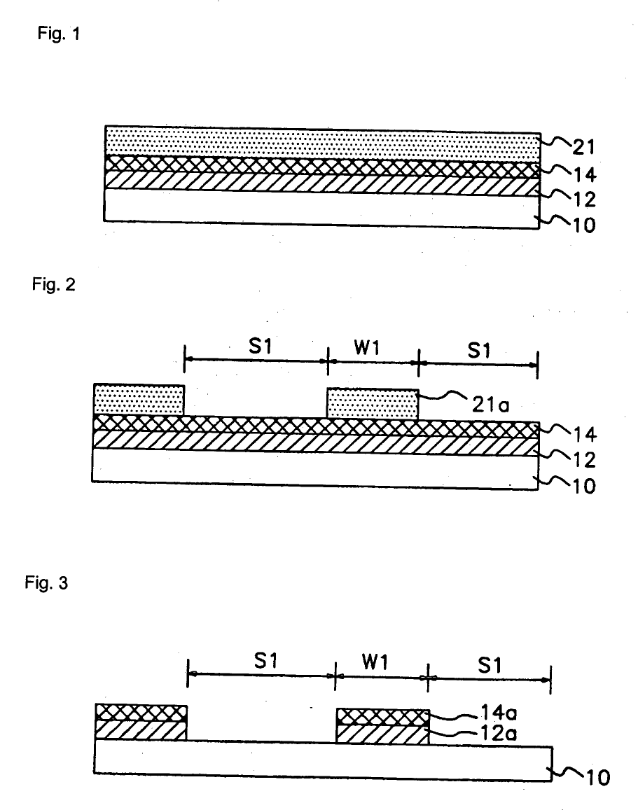

Prior to explaining the present invention, a conventional lithographic process for forming a pattern of a semiconductor device will be briefly explained. FIGS. 1-3 are cross-sectional views for illustrating a process for forming a pattern of a semiconductor device using conventional lithographic technology. In FIGS. 1-3, a gate electrode pattern is formed as an example of various patterns such as active region pattern, metal layer pattern, insulating layer pattern, etc. As shown in FIG. 1, a gate electrode material layer 12 made of a polysilicon layer is formed on a substrate 10. Then a gate capping layer 14 made of an insulating layer of an oxide layer, and a photoresist layer 21 are sequentially formed on the gate electrode material layer 12. The photoresist layer 21 can be formed with a positive photoresist. Referring to FIG. 2, the photoresist layer 21 is exposed and developed to form a photoresist pattern 21a. The spacing between the neighboring photoresist patterns 21a is symbolized as S1 and the line width of the photoresist patterns 21a is symbolized as W1. As shown in FIG. 3, the capping layer 14 and the gate electrode material layer 12 are etched by using the photoresist pattern 21a as a mask to form a gate electrode pattern 12a and a capping layer pattern 14a. The spacing between the adjacent gate electrode patterns 12a is the same with S1 and the line width of the gate electrode patterns 12a is the same with. W1. The spacing S1 and the line width W1 can be minimized to the resolution limit of the lithographic process, but cannot be reduced to be less than the resolution limit.

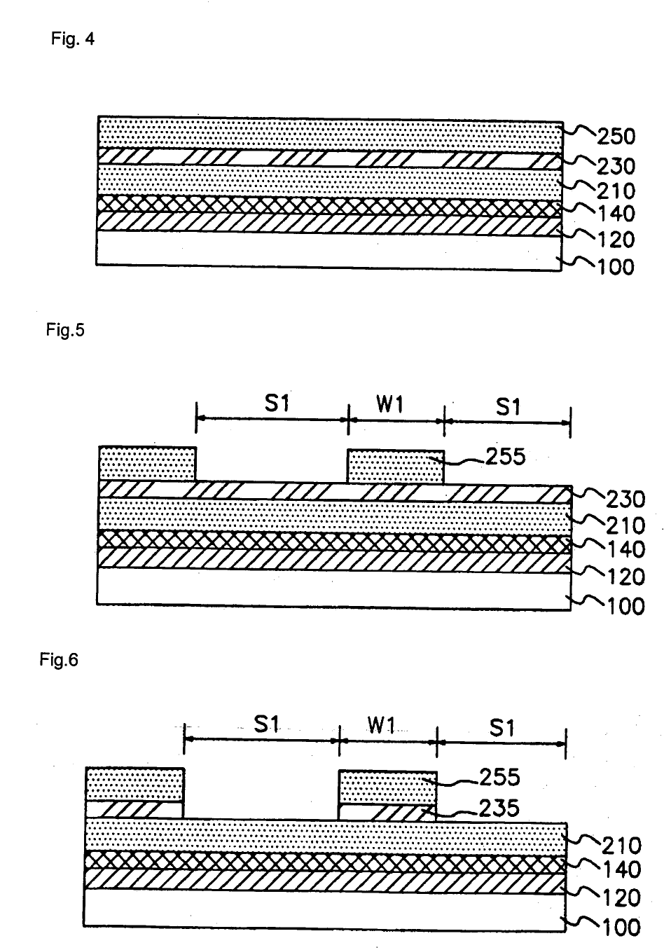

In contrast, the present invention provides a method for forming a pattern having a spacing of less than the resolution limit of the lithographic process. Hereinafter, the process for forming patterns of the semiconductor device according to an embodiment of the present invention will be described with reference to FIGS. 4-9. As shown in FIG. 4, a base layer, for example, gate electrode material layer 120 made of a polysilicon layer is formed on a semiconductor substrate 100, and a gate capping layer 140 made of an insulating layer of an oxide layer is optionally formed on the gate electrode material layer 120. Thereafter, a lower photoresist layer 210, a blocking layer 230 and an upper photoresist layer 250 are sequentially formed on the gate capping layer 140. The blocking layer 230 can be made of an insulating layer such as an oxide layer, or an anti-reflection layer. Preferably, the lower photoresist layer 210 and the upper photoresist layer 250 are produced with a positive photoresist, and the thickness of the lower photoresist layer 210 can be equal to that of the upper photoresist layer 250. Referring to FIG. 5, the first lithographic process is carried out to form the first photoresist pattern on the upper photoresist layer 250. Namely, the upper photoresist layer 250 is exposed by using the first mask (not shown) and developed to form a plurality of upper photoresist pattern lines 255. The upper photoresist pattern lines 255 are formed only on a part where odd numbered gate electrodes are formed. The odd numbered gate electrodes means gate electrodes formed at the odd numbered rows of a memory array. The spacing S1 between the adjacent upper photoresist pattern lines 255 and the width W1 of the upper photoresist pattern lines 255 are greater than the resolution limit of the lithographic process and the spacing S1 is greater than the width W1. As shown in FIG. 6, the blocking layer 230 is etched according to the first photoresist pattern by using the upper photoresist pattern lines 255 as a mask to form blocking pattern lines 235. If an oxide layer is used as the blocking layer 230, a separate step for etching the blocking layer 230 is necessary. However, if an anti-reflection layer is used as the blocking layer 230, the blocking layer 230 is etched while developing the upper photoresist layer 250 and the separate etching step is not necessary.

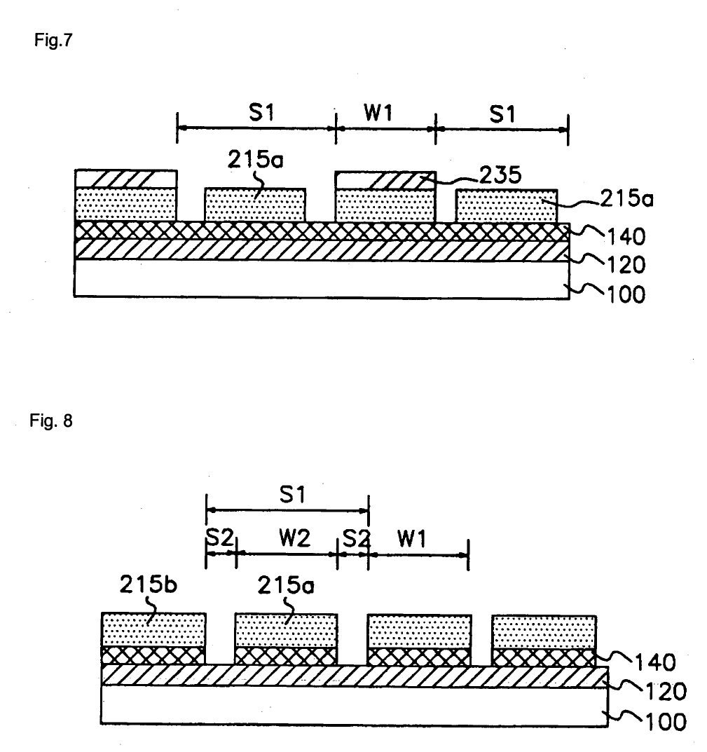

Referring to FIG. 7, the second photoresist pattern is formed on the lower photoresist layer 210 by the second lithographic process. Namely, the lower photoresist layer 210, which is opened by the spacing S1 of the first photoresist pattern, is exposed by using the second mask (not shown) and developed to form a plurality of lower photoresist pattern lines 215a. As already described, the spacing S1 between the upper photoresist pattern lines 255 is greater than the line width W1, therefore the lower photoresist pattern line 215a can be formed in the spacing S1. The second lithographic process is carried out so that the lower photoresist pattern lines 215a are formed only on a part where even numbered gate electrodes are formed. Preferably, the same first mask can be used as the second mask, or alternatively, another mask rather than the first mask can be used as the second mask. During the second lithographic process, the remaining upper photoresist patterns 255 can be removed while developing the lower photoresist layer 210 (See FIG. 7), and the lower photoresist layers 210 under the blocking patterns 235 are not removed due to the blocking patterns 235.

Thereafter, as shown in FIG. 8, the blocking patterns 235 and the gate capping layer 140 are removed by etching by using the second photoresist pattern as a mask, which produces gate pattern masks 215. The etching processes of the blocking patterns 235 and the gate capping layer 140 can be carried out at the same time or by separate process. Referring to FIG. 8, the gate pattern masks 215 comprise the first gate pattern masks 215a having the width of W2 and the second gate pattern masks 215b having the width of W1, which are formed alternatively. If the first mask and the second mask are the same, the width W2 of the first gate pattern mask 215a is equal to the width W1 of the second gate pattern mask 215b. The first gate pattern masks 215a can be formed in the spacing S1, and has the spacing S2 at each side of the first gate pattern masks 215a. Thus, the spacing S1, which is the spacing formed by the first photoresist pattern, is equal to 2S2+W2, and the spacing S2 between the first and the second gate pattern masks 215a, 215b is less than the spacing S1, and can be formed to be less than the resolution limit.

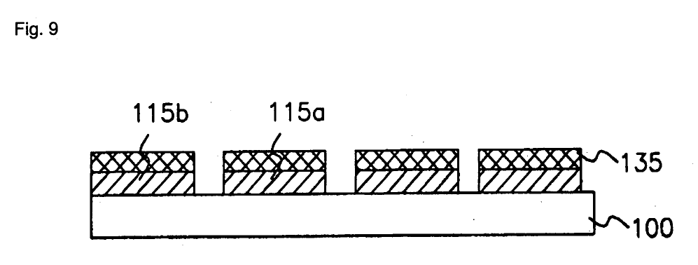

As shown in FIG. 9, after forming a plurality of gate pattern masks 215, the base layer, for example, the gate electrode material layer 120 is also etched by using the second photoresist pattern as a mask. If necessary, the gate electrode material layer 120 can be etched with the gate capping layer 140 at the same time. Then, the remaining photoresist layer, namely, the first and the second gate pattern masks 215a, 215b is removed by stripping to form the plurality of gate electrodes 115 including the even numbered gate electrodes 115a and the odd numbered gate electrodes 115b, which have the spacing of less than the resolution limit.

Although the present invention is described with reference to a specific embodiment for forming gate electrodes, the present invention is not limited thereto, and can be applied to any semiconductor pattern forming process having spacing of less than the resolution limit of a lithographic process. While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for forming a pattern of a semiconductor device, comprising the steps of:
(a) sequentially forming a base layer to be patterned, a lower photoresist layer, a blocking layer and an upper photoresist layer on a substrate;
(b) forming the first photoresist pattern on the upper photoresist layer, and etching the blocking layer according to the first photoresist pattern;
(c) forming the second photoresist pattern on the lower photoresist layer, which is opened by the spacing of the first photoresist pattern, wherein the spacing of the first photoresist pattern is greater than a line width of the second photoresist pattern;
(d) etching the base layer using the second photoresist pattern as a mask; and
(e) stripping the remaining photoresist layer.

2. The method for forming a pattern of a semiconductor device of claim 1, wherein the etched blocking layer prevents the lower photoresist layer under the blocking layer from being removed in the second photoresist pattern forming step.

3. The method for forming a pattern of a semiconductor device of claim 1, wherein the blocking layer is made of an insulating layer.

4. The method for forming a pattern of a semiconductor device of claim 1, wherein the blocking layer is an anti-reflection layer.

5. The method for forming a pattern of a semiconductor device of claim 1, wherein the lower photoresist layer and the upper photoresist layer are produced with a positive photoresist.

6. The method for forming a pattern of a semiconductor device of claim 1, wherein a spacing produced by the second photoresist pattern is less than the resolution limit of a lithographic process.

7. The method for forming a pattern of a semiconductor device of claim 1, wherein a spacing produced by the first photoresist pattern S1 is equal to 2S2+W2, wherein S2 represents a spacing produced at each side of the second photoresist pattern, and W2 represents a line width of the second photoresist pattern.
